(19) United States
(12) Patent Application Publication
(10) Pub. No.: US 2025/0160174 A1
(43) Pub. Date: May 15, 2025

(54) DISPLAY DEVICE AND METHOD OF FABRICATION FOR THE SAME

(71) Applicant: SAMSUNG DISPLAY CO., LTD., YONGIN-SI (KR)

(72) Inventors: Hyun Sup YOON, Yongin-si (KR); Jong Woo KIM, Yongin-si (KR); So Young OH, Yongin-si (KR); Woo Suk JUNG, Yongin-si (KR); Jae Heung HA, Yongin-si (KR)

(21) Appl. No.: 18/742,008

(22) Filed: Jun. 13, 2024

(30) Foreign Application Priority Data
Nov. 13, 2023 (KR) 10-2023-0156021

(51) Int. Cl. H10K 59/80; H10K 59/12

(52) U.S. Cl. CPC H10K 59/873; H10K 59/1201

(57) ABSTRACT

A display device that includes a light emitting element layer disposed on a substrate and including a plurality of light emitting elements and an encapsulation layer including an organic-inorganic hybrid layer disposed on the light emitting element layer, a first inorganic encapsulation layer disposed on the organic-inorganic hybrid layer, a second inorganic encapsulation layer disposed on the first inorganic encapsulation layer, and a third inorganic encapsulation layer disposed on the second inorganic encapsulation layer. The organic-inorganic hybrid layer contains silicon, carbon and nitrogen. The first inorganic encapsulation layer, the second inorganic encapsulation layer and the third inorganic encapsulation layer each contains silicon and nitrogen. An atomic ratio of nitrogen to silicon (N/Si ratio) in the organic-inorganic hybrid layer is greater than an atomic ratio of nitrogen to silicon (N/Si ratio) in the first inorganic encapsulation layer and an atomic ratio of nitrogen to silicon (N/Si ratio) in the third inorganic encapsulation layer.

### CROSS-REFERENCE TO RELATED APPLICATION

This application claims priority under 35 U.S.C. § 119 to Korean Patent Application No. 10-2023-0156021, filed on Nov. 13, 2023, in the Korean Intellectual Property Office, the disclosure of which is incorporated by reference herein in its entirety.

### 1. TECHNICAL FIELD

The present disclosure relates to a display device and a method of fabrication for the same.

### 2. DISCUSSION OF THE RELATED ART

As the information-oriented society advances, there is an increasing demand for display devices that can present images in various ways. For example, display devices find utility across various electronic devices such as smartphones, digital cameras, laptop computers, navigation devices, and smart televisions. The display device may be a flat panel display device such as a liquid crystal display (LCDs) device, a field emission display device and an organic light emitting display (OLEDs) device. Among the flat panel display devices, in the light emitting display device, since each of pixels of a display panel includes a light emitting element capable of emitting light by itself, an image can be displayed without the need for a backlight unit to provide light to the display panel.

The display device may further include pixels that emit predetermined light, scan lines, data lines, and power lines for driving the pixels, a scan driver that outputs scan signals to the scan lines, and a display driver that outputs data voltages to the data lines.

### SUMMARY

A display device that includes a light emitting element layer disposed on a substrate and including a plurality of light emitting elements and an encapsulation layer including an organic-inorganic hybrid layer disposed on the light emitting element layer, a first inorganic encapsulation layer disposed on the organic-inorganic hybrid layer, a second inorganic encapsulation layer disposed on the first inorganic encapsulation layer, and a third inorganic encapsulation layer disposed on the second inorganic encapsulation layer. The organic-inorganic hybrid layer contains silicon, carbon and nitrogen. The first inorganic encapsulation layer, the second inorganic encapsulation layer and the third inorganic encapsulation layer each contains silicon and nitrogen. An atomic ratio of nitrogen to silicon (N/Si ratio) in the organic-inorganic hybrid layer is greater than an atomic ratio of nitrogen to silicon (N/Si ratio) in the first inorganic encapsulation layer and an atomic ratio of nitrogen to silicon (N/Si ratio) in the third inorganic encapsulation layer.

A method of fabrication for a display device, including forming a light emitting element layer including a plurality of light emitting elements on a substrate, forming an organic-inorganic hybrid layer on the light emitting element layer at a first deposition rate, forming a first inorganic encapsulation layer on the organic-inorganic hybrid layer at a second deposition rate, forming a second inorganic encapsulation layer on the first inorganic encapsulation layer at a third deposition rate and forming a third inorganic encapsulation layer on the second inorganic encapsulation layer at a fourth deposition rate. The first deposition rate is greater than the second deposition rate and the fourth deposition rate, and the third deposition rate is greater than the second deposition rate and the fourth deposition rate.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment of the present invention;

FIG. 2 is a plan view showing the display device of FIG. 1;

FIG. 3 is a cross-sectional view taken along line A-A′ of FIG. 2;

FIG. 4 is a cross-sectional view showing one sub-pixel of a display device according to an embodiment of the present invention;

FIG. 5 is a schematic diagram showing an encapsulation layer of the display device according to an embodiment of the present invention;

FIG. 6 is a flowchart illustrating a method of fabrication for the display device according to an embodiment of the present invention;

FIGS. 7, 8, 9, 10 and 11 are diagrams sequentially showing a fabrication process of a display device according to an embodiment of the present invention;

FIG. 12 is a perspective view illustrating a head mounted display according to an embodiment of the present invention;

FIG. 13 is an exploded perspective view showing an example of the head mounted display of FIG. 12; and

FIG. 14 is a perspective view illustrating a head mounted display according to one embodiment.

### DETAILED DESCRIPTION OF THE EMBODIMENTS

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Hereinafter, embodiments will be described with reference to the accompanying drawings.

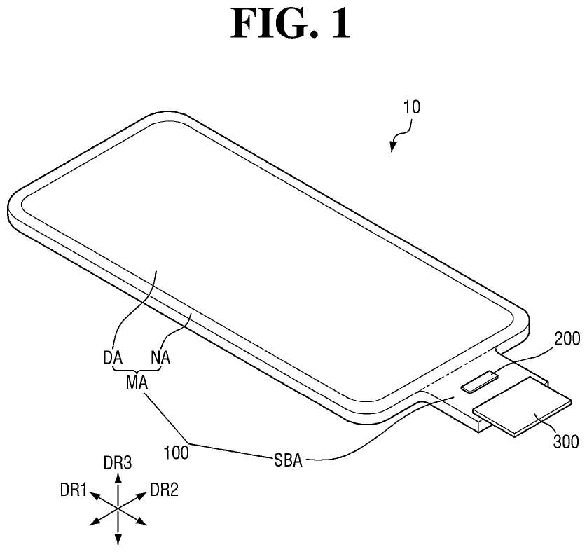

FIG. 1 is a perspective view of a display device according to an embodiment of the present invention.

Referring to FIG. 1, a display device 10 is a device for displaying a moving image or a still image. The display device 10 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). In the following, an embodiment in which the display device 10 is an organic light emitting display device is described, but the type of display device 10 is not necessarily limited thereto.

In an embodiment of the present invention, the display device 10 may be a flat structure. For example, the display device 10 may be formed substantially flat on a plane defined by a first direction DR1 and a second direction DR2 and may have a predetermined thickness (or height) along a third direction DR3. In some embodiments, the display device 10 may include a curved surface in at least a part which encompasses an edge region and the like. In addition, the display device 10 may be flexible so that it can be curved, bent, folded, or rolled.

In an embodiment of the present invention, with respect to the image display surface of the display device 10, the first direction DR1 may be a lengthwise direction, a column direction, or a vertical direction, and the second direction DR2 may be a direction intersecting the first direction DR1, for example, a widthwise direction, a row direction, or a horizontal direction. The third direction DR3 may be a thickness direction or a height direction of the display device 10.

The display device 10 may include a display panel 100, a driver 200, and a circuit board 300.

The display panel 100 may include a main region MA including a display area DA in which an image is displayed, and a sub-region SBA located on one side of the main region MA.

The main region MA may include the display area DA and a non-display area NA surrounding the display area DA. The display area DA may be positioned in the center of the main region MA and occupy most of the area in the main region MA. The non-display area NA may be positioned at an edge of the main region MA and may be in contact with the sub-region SBA.

The display area DA may be an area in which pixels are arranged, and may be an area in which an image is displayed by pixels. In an embodiment of the present invention, the display area DA may be further provided with sensing patterns (e.g., touch electrodes) for detecting a touch input and the like, and the display area DA may include a sensing area for detecting a touch input by the sensing patterns.

In an embodiment of the present invention, the display area DA may include a long side in the first direction DR1 and a short side in the second direction DR2 and may be formed as a plane having an approximately rectangular shape. A corner where the long side and the short side of the display area DA intersect may be rounded or right-angled. The shape of the display area DA may vary according to embodiments. For example, the display area DA may be a polygonal shape other than a quadrilateral shape, a circular shape, an elliptical shape, or the like.

The non-display area NA may be located immediately around the display area DA. For example, the non-display area NA may at least partially surround the display area DA. An embedded circuit may be disposed in the non-display area NA. For example, an embedded circuit including a scan driving circuit or the like may be disposed in the non-display area NA positioned on one side (e.g., the left side or the right side) or both sides of the display area DA.

The sub-region SBA may be located on a side of the main region MA. For example, the sub-region SBA may be a region protruding along the first direction DR1 from one side of the main region MA. For example, the sub-region SBA may protrude along the first direction DR1 from the lower end of the main region MA. In an embodiment of the present invention, the sub-region SBA may have a narrower width than the main region MA. For example, with respect to the second direction DR2, the sub-region SBA may have a narrower width than the main region MA.

Wires and pads may be disposed in the sub-region SBA. For example, in the sub-region SBA, the wires and pads connected to the pixels and/or the embedded circuit positioned in the main region MA and to the driver 200 and/or the circuit board 300 positioned in the sub-region SBA may be disposed. In describing embodiments, the term “connect” may include electrical connection and/or physical connection.

In an embodiment of the present invention, the driver 200 (e.g., the display driving circuit) may be mounted in the sub-region SBA. The circuit board 300 may be disposed on a part of the sub-region SBA.

The driver 200 may include a data driving circuit that drive pixels. In an embodiment of the present invention, the driver 200 may be formed as an integrated circuit chip (IC) and disposed in the sub-region SBA. In some embodiments, the driver 200 may be disposed on the circuit board 300 disposed on the sub-region SBA or may be disposed on another circuit board connected to the display panel 100 through the circuit board 300.

The circuit board 300 may be disposed on a part of the sub-region SBA. For example, the circuit board 300 may be bonded on the pads positioned on a portion (e.g., a lower edge) of the sub-region SBA. The circuit board 300 may supply power or transmit driving signals that drives the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip on film (COF), but is not necessarily limited thereto.

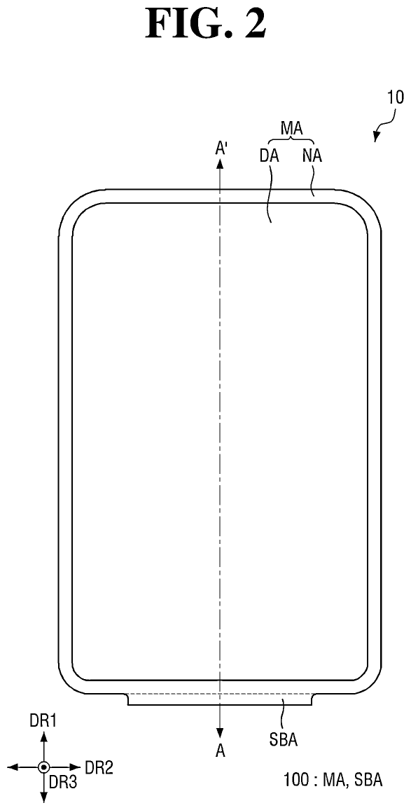

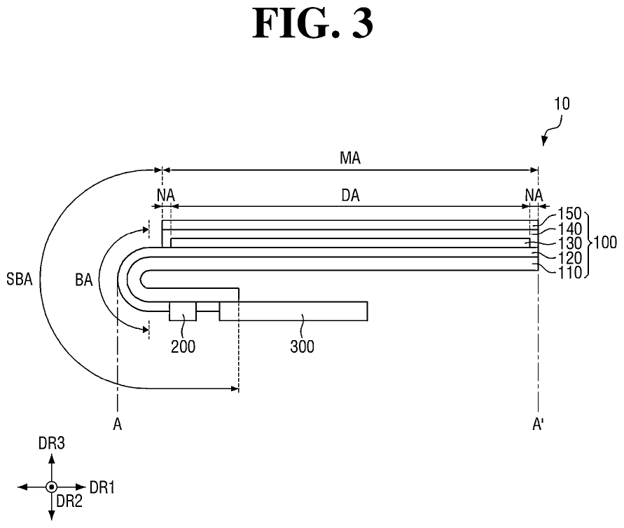

FIG. 2 is a plan view showing the display device of FIG. 1. FIG. 3 is a cross-sectional view taken along line A-A′ of FIG. 2.

FIG. 1 illustrates the display device 10 unfolded without bending, and FIGS. 2 and 3 illustrate the display device 10 bent in the sub-region SBA. FIG. 1 shows the sub-region SBA unfolded alongside the main region MA, and FIGS. 2 and 3 show a part of the sub-region SBA in a bent state.

Referring to FIGS. 2 and 3, the display panel 100 may include a substrate 110 including the main region MA and the sub-region SBA, a circuit layer 120, a light emitting element layer 130, an encapsulation layer 140, and a color filter layer 150 sequentially disposed on the substrate 110. The circuit layer 120 may also be positioned in the main region MA and the sub-region SBA. The light emitting element layer 130, the encapsulation layer 140, and the color filter layer 150 may be positioned on a part of the substrate 110 and the circuit layer 120. For example, the light emitting element layer 130, the encapsulation layer 140, and the color filter layer 150 may be positioned in the main region MA.

In an embodiment of the present invention, the display device 10 may further include an additional element disposed on the display panel 100. For example, the display device 10 may further include at least one of a sensor layer (e.g., a touch sensor layer), a polarization layer, and a protective layer (e.g., a window) disposed on the encapsulation layer 140. Each of the sensor layer, the polarization layer and/or the protective layer may be fabricated integrally with the display panel 100 or may be fabricated separately from the display panel 100 and attached to the display panel 100 through an adhesive layer or the like.

The main region MA may include the display area DA and the non-display area NA. The non-display area NA may be located adjacent to the display area DA. For example, the non-display area NA may be an edge area of the main region MA positioned outside the display area DA. For example, the display area DA may be disposed between the non-display areas NA.

The substrate 110 may include an insulating material such as a polymer resin. For example, the substrate 110 may be made of polyimide or another insulating material. The substrate 110 may be a flexible substrate that can be transformed, such as bending, folding, or rolling. In some embodiments, the substrate 110 may include an insulating material such as glass.

The circuit layer 120 may include pixel circuits and wires. For example, the circuit layer 120 may include circuit elements (e.g., pixel transistors and capacitors) constituting a pixel circuit for each pixel, and wires connected to the pixels. In an embodiment of the present invention, the circuit layer 120 may further include circuit elements constituting an embedded circuit, such as a scan driving circuit, and wires connected to the embedded circuit.

The light emitting element layer 130 may include light emitting elements disposed in emission areas of the pixels. For example, each of the pixels may include at least one light emitting element and a pixel circuit connected to the light emitting element. Each of the pixels may be located in a pixel region including the emission area where the light emitting element is disposed and a pixel circuit area where the pixel circuit is disposed. The emission area and the pixel circuit area of each pixel may overlap each other, but the present disclosure is not necessarily limited thereto.

In describing the embodiments, the circuit layer 120 and the light emitting element layer 130 are separately described, but the embodiments are not necessarily limited thereto. For example, the circuit layer 120 and the light emitting element layer 130 may be integrated.

The encapsulation layer 140 may at least partially cover the light emitting element layer 130. The encapsulation layer 140 may extend from an non-display area NA towards another non-display area NA and be in contact with the circuit layer 120. In an embodiment of the present invention, the encapsulation layer 140 may have a multilayer structure including at least two inorganic encapsulation layers overlapping each other and at least one organic encapsulation layer interposed between the inorganic encapsulation layers.

In an embodiment of the present invention, the display panel 100 may be bent in a bending area BA. The bending area BA may be a part of the sub-region SBA and may be spaced apart from the main region MA. The non-display area NA may be interposed between the bending area BA and the display area DA.

The substrate 110 and the circuit layer 120 may be bent in the bending area BA corresponding to a partial section of the sub-region SBA. Accordingly, the bezel area recognized by a user as the non-display area NA may be reduced or minimized.

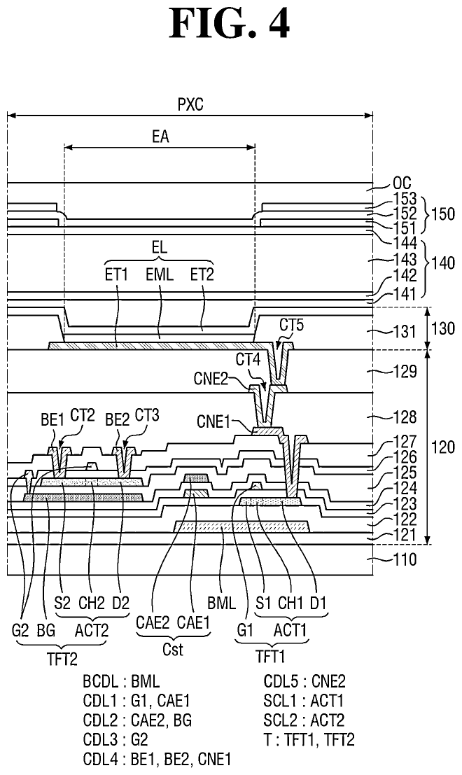

FIG. 4 is a cross-sectional view showing one sub-pixel of a display device according to an embodiment of the present invention. FIG. 4 is a cross-sectional view showing a part of an area corresponding to one sub-pixel of the display area DA.

Referring to FIG. 4, the display panel 100 may include the substrate 110, and the circuit layer 120, the light emitting element layer 130, the encapsulation layer 140, and the color filter layer 150 disposed on the substrate 110. The circuit layer 120, the light emitting element layer 130, the encapsulation layer 140, and the color filter layer 150 may be sequentially arranged or stacked on the substrate 110 along the third direction DR3.

The substrate 110 may be made of a material having a flexible characteristic capable of bending, folding, rolling, or the like. The substrate 110 may include an insulating material such as a polymer resin. For example, the substrate 110 may be made of polyimide.

The circuit layer 120 may include a pixel circuit PXC and wires. For example, the circuit layer 120 may include circuit elements (e.g., pixel transistors T and a capacitor Cst) constituting the pixel circuit PXC of each sub-pixel, and wires (e.g., various power lines and signal lines including the power lines, the scan lines, emission control lines, and the data lines) electrically connected to the sub-pixels.

Among elements that may be provided on the circuit layer 120, FIG. 4 illustrates the pixel circuit PXC of each sub-pixel including a first thin film transistor TFT1 (also referred to as a “first pixel transistor”), a second thin film transistor TFT2 (also referred to as a “second pixel transistor”), and the capacitor Cst. The first thin film transistor TFT1 may represent first type transistors (e.g., P-type transistors) including a first semiconductor material (e.g., polysilicon) among the pixel transistors T constituting each pixel circuit PXC. FIG. 4 illustrates the first thin film transistor TFT1, a transistor connected to the light emitting element EL through at least one connection electrode (e.g., a first connection electrode CNE1 and a second connection electrode CNE2) among the first type transistors. The second thin film transistor TFT2 may represent second type transistors (e.g., N-type transistors) including a second semiconductor material (e.g., oxide semiconductor) among the pixel transistors T.

Cross sections of the sub-pixels may be vary according to each of the sub-pixels and the type and/or structure of the display panel 100 including the sub-pixel. For example, positions and order of formation of the first thin film transistor TFT1, the second thin film transistor TFT2, and the capacitor Cst may vary according to embodiments.

The circuit layer 120 may include semiconductor layers that form circuit elements, wires, or the like, conductive layers, and insulating layers disposed between and/or around the conductive layers and the semiconductor layers. For example, the circuit layer 120 may include a first semiconductor layer SCL1 (e.g., a polysilicon semiconductor layer), a first insulating layer 123 (e.g., a first gate insulating layer), a first conductive layer CDL1 (e.g., a first gate conductive layer), a second insulating layer 124 (e.g., a second gate insulating layer), a second conductive layer CDL2 (e.g., a second gate conductive layer), a third insulating layer 125 (e.g., a first interlayer insulating layer), a second semiconductor layer SCL2 (e.g., an oxide semiconductor layer), a fourth insulating layer 126 (e.g., a third gate insulating layer), a third conductive layer CDL3 (e.g., a third gate conductive layer), a fifth insulating layer 127 (e.g., a second interlayer insulating layer), a fourth conductive layer CDL4 (e.g., a first source-drain conductive layer), and a sixth insulating layer 128 (e.g., a first via layer or a first planarization layer) sequentially disposed on the substrate 110 with respect to the third direction DR3. In an embodiment of the present invention, the circuit layer 120 may further include a fifth conductive layer CDL5 (e.g., a second source-drain conductive layer) and a seventh insulating layer 129 (e.g., a second via layer or a second planarization layer) sequentially disposed on the sixth insulating layer 128. In an embodiment of the present invention, the circuit layer 120 may further include a lower conductive layer BCDL disposed between the substrate 110 and the first semiconductor layer SCL1, a barrier layer 121 disposed between the substrate 110 and the lower conductive layer BCDL, and a buffer layer 122 disposed between the lower conductive layer BCDL and the first semiconductor layer SCL1.

The barrier layer 121 may be disposed on the substrate 110. For example, the barrier layer 121 may be in direct contact with the substrate 110. The barrier layer 121 may protect elements disposed on the circuit layer 120 and the light emitting element layer 130 from moisture permeating through the substrate 110 that is susceptible to moisture permeation. The barrier layer 121 may include at least one inorganic layer containing an inorganic insulating material (e.g., silicon nitride, silicon oxide, silicon oxynitride, titanium oxide, aluminum oxide, or another inorganic insulating material). The material of the barrier layer 121 may vary according to embodiments.

The lower conductive layer BCDL may be disposed on the barrier layer 121. The lower conductive layer BCDL may include a lower metal layer BML overlapping the active layer (e.g., a first active layer ACT1 and/or a second active layer ACT2) of the at least one pixel transistor T, and/or at least one wire (or a part of the at least one wire). FIG. 4 illustrates that the lower metal layer BML is disposed to overlap only the first active layer ACT1 of the first thin film transistor TFT1 and capacitor electrodes CAE1 and CAE2 of the capacitor Cst, but the present disclosure is not limited thereto. For example, the lower metal layer BML may be patterned into an appropriate size and/or shape as needed and disposed on a part of the pixel circuit PXC, or may be disposed on the entire surface of the pixel circuit PXC. In an embodiment of the present invention, the lower metal layer BML may also be utilized as a light blocking pattern and/or a back-gate electrode of at least one pixel transistor T, or the like.

The buffer layer 122 may be disposed on the lower conductive layer BCDL and at least partially cover the lower conductive layer BCDL. The buffer layer 122 may include at least one inorganic layer containing an inorganic insulating material.

The first thin film transistor TFT1, the second thin film transistor TFT2, and thecapacitor Cst may be disposed on one surface of the substrate 110 including the buffer layer 122. The first thin film transistor TFT1 may include the first active layer ACT1 and a first gate electrode G1. The second thin film transistor TFT2 may include the second active layer ACT2 and a second gate electrode G2. In an embodiment of the present invention, the second thin film transistor TFT2 may include a back-gate electrode BG. The capacitor Cst may include a first capacitor electrode CAE1 and a second capacitor electrode CAE2.

The first semiconductor layer SCL1 may be disposed on the buffer layer 122. The first semiconductor layer SCL1 may include the first active layer ACT1 of the first thin film transistor TFT1.

The first active layer ACT1 may be provided on the first semiconductor layer SCL1 and may include a first semiconductor material (e.g., polysilicon). The first active layer ACT1 may include a first channel region CH1, a first source region S1, and a first drain region D1. The first channel region CH1 may overlap the first gate electrode G1 along the third direction DR3. The first source region S1 may be disposed on one side of the first channel region CH1, and the first drain region D1 may be disposed on the other side of the first channel region CH1. For example, the first channel region CH1 may be interposed between the first source region S1 and the first drain region D1. The first source region S1 and the first drain region D1 may be regions formed to have conductivity by doping ions or impurities into a semiconductor for forming the first active layer ACT1. In an embodiment of the present invention, the first source region S1 may be a source electrode of the first thin film transistor TFT1. In some embodiments, the first thin film transistor TFT1 may include a separate source electrode connected to the first source region S1. In an embodiment of the present invention, the first drain region D1 may be a drain electrode of the first thin film transistor TFT1. In some embodiments, the first thin film transistor TFT1 may include a separate drain electrode connected to the first drain region D1.

The first insulating layer 123 may be disposed on the first semiconductor layer SCL1. The first insulating layer 123 may cover the first semiconductor layer SCL1.

The first conductive layer CDL1 may be disposed on the first insulating layer 123. The first conductive layer CDL1 may include the first gate electrode G1 of the first thin film transistor TFT1. The first gate electrode G1 may be disposed to overlap a part of the first active layer ACT1 (e.g., the first channel region CH1). In an embodiment of the present invention, the first conductive layer CDL1 may further include at least one wire (or a part of the at least one wire), a metal pattern (e.g., a bridge pattern), and/or a capacitor electrode. For example, the first conductive layer CDL1 may further include the first capacitor electrode CAE1 of the capacitor Cst.

In an embodiment of the present invention, the first capacitor electrode CAE1 may be integrally formed with the gate electrode G1 of at least one first thin film transistor TFT1. For example, the first capacitor electrode CAE1 and the gate electrode G1 of the first thin film transistor TFT1 may be formed as one conductive pattern, and the second capacitor electrode CAE2 may overlap the conductive pattern.

The second insulating layer 124 may be disposed on the first conductive layer CDL1. The second insulating layer 124 may at least partially cover the first conductive layer CDL1.

The second conductive layer CDL2 may be disposed on the second insulating layer 124. The second conductive layer CDL2 may include one electrode of the capacitor Cst, for example, the second capacitor electrode CAE2. In an embodiment of the present invention, the second conductive layer CDL2 may further include at least one electrode, a wire (or a part of the at least one wire), and/or a metal pattern (e.g., a bridge pattern). For example, the second conductive layer CDL2 may further include the back-gate electrode BG connected to the second gate electrode G2 of the second thin film transistor TFT2.

The third insulating layer 125 may be disposed on the second conductive layer CDL2 The third insulating layer 125 may at least partially cover the second conductive layer CDL2.

The second semiconductor layer SCL2 may be disposed on the third insulating layer 125. The second semiconductor layer SCL2 may include the second active layer ACT2 of the second thin film transistor TFT2.

The second active layer ACT2 may be provided on the second semiconductor layer SCL2 and may include a second semiconductor material (e.g., an oxide semiconductor) different from the first semiconductor material. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn), and oxygen (O)).

The second active layer ACT2 may include a second channel region CH2, a second source region S2, and a second drain region D2. The second channel region CH2 may overlap the second gate electrode G2 along the third direction DR3. The second source region S2 may be disposed on one side of the second channel region CH2, and the second drain region D2 may be disposed on the other side of the second channel region CH2. For example, the second channel region CH2 may be interposed between the second source region S2 and the second drain region D2. The second source region S2 and the second drain region D2 may be conductive regions by doping ions or impurities into a semiconductor for forming the second active layer ACT2. In an embodiment of the present invention, the second source region S2 may be a source electrode of the second thin film transistor TFT2. In some embodiments, the second thin film transistor TFT2 may include a separate source electrode connected to the second source region S2. In an embodiment of the present invention, the second drain region D2 may be a drain electrode of the second thin film transistor TFT2. In some embodiments, the second thin film transistor TFT2 may include a separate drain electrode connected to the second drain region D2.

The fourth insulating layer 126 may be disposed on the second semiconductor layer SCL2. The fourth insulating layer 126 may cover the second semiconductor layer SCL2.

The third conductive layer CDL3 may be disposed on the fourth insulating layer 126. The third conductive layer CDL3 may include the second gate electrode G2 of the second thin film transistor TFT2. The second gate electrode G2 may be disposed to overlap a part of the second active layer ACT2 (e.g., the second channel region CH2). In an embodiment of the present invention, the third conductive layer CDL3 may further include at least one wire (or a part of the at least one wire), a metal pattern (e.g., a bridge pattern), and/or a capacitor electrode.

In an embodiment of the present invention, each of the electrodes, the conductive patterns, and/or the wires provided in the lower conductive layer BCDL, the first conductive layer CDL1, the second conductive layer CDL2, and the third conductive layer CLD3 may include a conductive material (e.g., molybdenum (Mo), aluminum (Al), chromium (Cr), gold (Au), titanium (Ti), nickel (Ni), neodymium (Nd), copper (Cu), and at least one of other metals, alloys thereof, or other conductive materials), and may each have a single layer or multilayer structure. For example, each of the electrodes, the conductive patterns, and/or the wires provided in the lower conductive layer BCDL, the first conductive layer CDL1, the second conductive layer CDL2, and the third conductive layer CLD3 may include molybdenum (Mo) or other metal materials. At least two conductive layers among the lower conductive layer BCDL, the first conductive layer CDL1, the second conductive layer CDL2, and the third conductive layer CLD3 may include the same material or may include different materials. However, materials of each of the lower conductive layer BCDL, the first conductive layer CDL1, the second conductive layer CDL2, and the third conductive layer CLD3 are not necessarily limited thereto, and may be vary according to embodiments.

The fifth insulating layer 127 may be disposed on the third conductive layer CDL3. The fifth insulating layer 127 may cover the third conductive layer CDL3.

In an embodiment of the present invention, the first insulating layer 123, the second insulating layer 124, the third insulating layer 125, the fourth insulating layer 126, and the fifth insulating layer 127 may be an inorganic insulating layer including an inorganic insulating material (e.g., silicon nitride, silicon oxide, silicon oxynitride, titanium oxide, aluminum oxide, or another inorganic insulating material), and each may have a single layer or multilayer structure. At least two insulating layers among the first insulating layer 123, the second insulating layer 124, the third insulating layer 125, the fourth insulating layer 126, and the fifth insulating layer 127 may include the same material or may include different materials. Materials of each of the first insulating layer 123, the second insulating layer 124, the third insulating layer 125, the fourth insulating layer 126, and the fifth insulating layer 127 may vary according to embodiments.

The fourth conductive layer CDL4 may be disposed on the fifth insulating layer 127. The fourth conductive layer CDL4 may include the first connection electrode CNE1 (or a drain electrode of the first thin film transistor TFT1), a first bridge electrode BE1 (or a source electrode of the second thin film transistor TFT2), and a second bridge electrode BE2 (or a drain electrode of the second thin film transistor TFT2). The first connection electrode CNE1 may be provided on the fourth conductive layer CDL4 and may be connected to the first drain region D1 of the first active layer ACT1 through a first contact hole CT1 penetrating the first insulating layer 123, the second insulating layer 124, the third insulating layer 125, the fourth insulating layer 126, and the fifth insulating layer 127. The first bridge electrode BE1 may be provided on the fourth conductive layer CDL4 and may be connected to the second source region S2 of the second active layer ACT2 through a second contact hole CT2 penetrating the fourth insulating layer 126 and the fifth insulating layer 127. The second bridge electrode BE2 may be connected to the second drain region D2 of the second active layer ACT2 through a third contact hole CT3 penetrating the fourth insulating layer 126 and the fifth insulating layer 127. In an embodiment of the present invention, the fourth conductive layer CDL4 may further include at least one wire (or a part of the at least one wire), and/or a metal pattern (e.g., a bridge pattern). For example, the fourth conductive layer CDL4 may include a part of the power line (e.g., the first pixel power line and/or the second pixel power line) provided inside and/or outside the display area DA.

The sixth insulating layer 128 may be disposed on the fourth conductive layer CDL4. The sixth insulating layer 128 may at least partially cover the fourth conductive layer CDL4.

The fifth conductive layer CDL5 may be disposed on the sixth insulating layer 128. The fifth conductive layer CDL5 may include the second connection electrode CNE2. The second connection electrode CNE2 may be provided on the fifth conductive layer CDL5 and may be connected to the first connection electrode CNE1 through a fourth contact hole CT4 (or a first via hole) penetrating the sixth insulating layer 128. In an embodiment of the present invention, the fifth conductive layer CDL5 may further include at least one wire (or a part of the at least one wire), and/or a metal pattern (e.g., a bridge pattern). For example, the fifth conductive layer CDL5 may include a part of the power line (e.g., the first pixel power line and/or the second pixel power line) provided inside and/or outside the display area DA.

In an embodiment of the present invention, each of the electrodes, the conductive patterns, and/or the wires provided in the fourth conductive layer CDL4 and the fifth conductive layer CDL5 may include a conductive material (e.g., molybdenum (Mo), aluminum (Al), chromium (Cr), gold (Au), titanium (Ti), nickel (Ni), neodymium (Nd), copper (Cu), and at least one of other metals, alloys thereof, or other conductive materials), and may have a single layer or multilayer structure. For example, each of the electrodes, the conductive patterns, and/or the wires provided in the fourth conductive layer CDL4 and the fifth conductive layer CDL5 may be formed of a triple layer structure including titanium/aluminum/titanium (Ti/Al/Ti). The fourth conductive layer CDL4 and the fifth conductive layer CDL5 may include the same material or may include different materials. Materials of each of the fourth conductive layer CDL4 and the fifth conductive layer CDL5 may vary according to embodiments.

The seventh insulating layer 129 may be disposed on the fifth conductive layer CDL5. The seventh insulating layer 129 may at least partially cover the fifth conductive layer CDL5.

In an embodiment of the present invention, the sixth insulating layer 128 and the seventh insulating layer 129 may be an organic insulating layer including an organic insulating material (e.g., acrylic resin, epoxy resin, phenolic resin, polyamide resin, polyimide resin, or other organic insulating material) that planarize the circuit layer 120, and may each have a single layer or multilayer structure. The sixth insulating layer 128 and the seventh insulating layer 129 may include the same material or may include different materials. Materials of each of the sixth insulating layer 128 and the seventh insulating layer 129 may vary according to embodiments.

The light emitting element layer 130 may include a pixel defining layer 131 that partitions emission areas EA of the pixels and the respective light emitting elements EL positioned in the respective emission areas EA. In an embodiment of the present invention, the light emitting element layer 130 may further include a spacer disposed on a part of the pixel defining layer 131.

Each of the light emitting elements EL may include a first electrode ET1 (e.g., an anode electrode) connected to at least one transistor T (e.g., the first thin film transistor TFT1) included in the corresponding sub-pixel through the first connection electrode CNE1 and/or the second connection electrode CNE2, and a light emitting layer EML and a second electrode ET2 (e.g., a cathode electrode) sequentially disposed on the first electrode ET1. In an embodiment of the present invention, the light emitting element EL may further include a first intermediate layer (e.g., hole layer including a hole transport layer) interposed between the first electrode ET1 and the light emitting layer EML, and a second intermediate layer (e.g., an electron layer including an electron transport layer) interposed between the light emitting layer EML and the second electrode ET2.

The first electrode ET1 of the light emitting element EL may include a conductive material and may be disposed on the circuit layer 120. For example, the first electrode ET1 may be disposed on the seventh insulating layer 129 and correspond to each emission area EA. The first electrode ET1 may be connected to the second connection electrode CNE2 through a fifth contact hole CT5 (or a second via hole) penetrating the seventh insulating layer 129.

In an embodiment of the present invention, the first electrode ET1 may include transparent conductive metal oxide or a metal material having high reflectivity. For example, the first electrode ET1 may have a single-layer structure including molybdenum (Mo), titanium (Ti), copper (Cu) or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light emitting layer EML of the light emitting element EL may include a high molecular material or a single molecular material. In an embodiment of the present invention, the light emitting layer EML of the light emitting element EL may be disposed for each sub-pixel, and the light emitting layer EML of each sub-pixel may emit visible light of a color corresponding to the corresponding sub-pixel. In some embodiments, the light emitting layer EML may be a common layer shared by the sub-pixels of different colors, and a wavelength conversion layer and/or color filters corresponding to the color (or wavelength band) of light desired to be emitted from each sub-pixel may be arranged in the emission areas EA of at least some of the sub-pixels.

The second electrode ET2 of the light emitting element EL includes a conductive material and may be connected to the second pixel power line. In an embodiment of the present invention, the second electrode ET2 may be a common layer formed across the entire display area DA that at least partially covers the light emitting layer EML and the pixel defining layer 131. In an embodiment of the present invention, the second electrode ET2 may include transparent conductive oxide (TCO) such as Indium Tin Oxide (ITO) or Indium Zinc Oxide (IZO) capable of transmitting light or a semi-transmissive conductive material such as magnesium (Mg), silver (Ag), or an alloy of magnesium (Mg) and silver (Ag). When the second electrode ET2 includes a semi-transmissive conductive material, an improvement in light output efficiency due to a micro cavity effect may be expected.

In some embodiments, a capping layer may be disposed on the second electrode ET2. The capping layer may include an organic or inorganic insulating material that at least partially covers the light emitting element EL. The capping layer may prevent the light emitting element EL from being damaged by external air. In an embodiment of the present invention, the capping layer may include an organic material, such as alpha-Naphthylphenylamine (a-NPD), N,N′-Di(naphthalen-1-yl)-N,N′-diphenylbenzidine (NPB), Triphenylamine-based hole Transporting Material (TPD), 1,3,5-tri [(3-pyridyl)-phen-3-yl]benzene (m-MTDATA), tris(8-hydroxyquinolinato)aluminum (Alq3), lithium fluoride (LiF), and/or copper phthalocyaninc (CuPc). Alternatively, it may include an inorganic material, such as aluminum oxide (Al2O3), titanium oxide (TiO2), tantalum oxide (Ta2O5), hafnium oxide (HfO2), zinc oxide (ZnO), silicon oxide (SiO2), silicon nitride (Si3N4), and/or silicon oxynitride (SiON).

The pixel defining layer 131 may have an opening corresponding to each of the emission areas EA and may at least partially surround the emission areas EA. For example, the pixel defining layer 131 may cover an edge of the first electrode ET1 of the light emitting element EL and may include an opening exposing the remaining portion of the first electrode ET1. A region where the exposed first electrode ET1 and the light emitting layer EML overlap (or a region including the same) may be defined as the emission area EA of each pixel PX.

In an embodiment of the present invention, the pixel defining layer 131 may include at least one organic layer containing an organic insulating material. For example, the pixel defining layer 131 may include polyacrylic resin (PAR), epoxy resin (ER), phenolic resin (PR), polyamide resin (PA), polyimide resin (PI), unsaturated polyester resin (UPR), polyphenylene ether resin (PPER), polyphenylenesulfide resin (PPSR), benzocyclobutene (BCB), or other organic insulating materials.

The spacer may be disposed on a part of the pixel defining layer 131. The spacer may include at least one organic layer containing an organic insulating material. In an embodiment of the present invention, the spacer may include the same material as the pixel defining layer 131 or may include a different material from the pixel defining layer 131. The organic insulating material constituting the spacer is not necessarily limited and vary according to embodiments.

The encapsulation layer 140 may be disposed on the light emitting element layer 130 in the main region MA. For example, the encapsulation layer 140 may be disposed in the display area DA and the non-display area NA and at least partially cover the light emitting element layer 130. The encapsulation layer 140 may block the permeation of oxygen or moisture into the light emitting element layer 130, and may reduce electrical or physical impacts to the circuit layer 120 and the light emitting element layer 130.

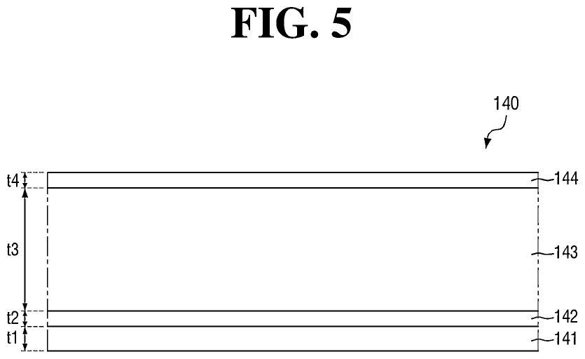

FIG. 5 is a schematic diagram showing an encapsulation layer of the display device according to an embodiment of the present invention.

Referring to FIG. 5, the encapsulation layer 140 may include an organic-inorganic hybrid layer 141, a first inorganic encapsulation layer 142, a second inorganic encapsulation layer 143, and a third inorganic encapsulation layer 144 sequentially disposed on the light emitting element layer 130 (refer to FIG. 4). Even when comprised of multiple stacked layers, the encapsulation layer 140 may remain relatively thin.

The organic-inorganic hybrid layer 141 may include organic groups or organic moieties interspersed with an inorganic material. In an embodiment of the present invention, the organic-inorganic hybrid layer 141 may include silicon (Si), carbon (C), and nitrogen (N). The organic-inorganic hybrid layer 141 may include silicon oxycarbonitride (SiOxCyNz) or silicon carbonitride (SiCyNz). The organic-inorganic hybrid layer 141 may include silicon (Si), carbon (C), and nitrogen (N) in one layer, thereby lowering the film density while maintaining barrier properties and planarization properties.

The organic groups or organic moieties may be randomly arranged within the organic-inorganic hybrid layer 141. In an embodiment of the present invention, the organic moiety may include carbon (C) and nitrogen (N) and may additionally include oxygen (O) or sulfur(S). However, the present disclosure is not necessarily limited thereto, and may also include other elements. In an embodiment of the present invention, the organic moiety may include at least one of an alkyl group and an alkoxy group and an amine group. The alkyl group, alkoxy group, or amine group may be derived from an organic silicon precursor and an aminosilane precursor later described in the manufacturing method.

The first inorganic encapsulation layer 142, the second inorganic encapsulation layer 143, and the third inorganic encapsulation layer 144 may include an inorganic insulating material. The inorganic insulating material may include aluminum oxide (Al2O3), titanium oxide (TiO2), tantalum oxide (Ta2O5), hafnium oxide (HfO2), zinc oxide (ZnO), silicon oxide (SiO2), silicon nitride (Si3N4), and/or silicon oxynitride (SiON), but is not necessarily limited thereto.

In an embodiment of the present invention, the first inorganic encapsulation layer 142, the second inorganic encapsulation layer 143, and the third inorganic encapsulation layer 144 may each include silicon (Si) and nitrogen (N). The first to third inorganic encapsulation layers 142 to 144 may each include silicon nitride (SiNz) or silicon oxynitride (SiOₓN_{z}). Nitrogen content (z) contained in the first to third inorganic encapsulation layers 142, 143, and 144 may be the same or different from each other.

The atomic ratio of nitrogen to silicon (N/Si ratio) in the organic-inorganic hybrid layer 141 may be greater than the atomic ratio of nitrogen to silicon (N/Si ratio) in the first inorganic encapsulation layer 142, and the atomic ratio of nitrogen to silicon (N/Si ratio) in the third inorganic encapsulation layer 144. The atomic ratio of nitrogen to silicon (N/Si ratio) in the first inorganic encapsulation layer 142 may be smaller than the atomic ratio of nitrogen to silicon (N/Si ratio) in the organic-inorganic hybrid layer 141, and the atomic ratio of nitrogen to silicon (N/Si ratio) in the second inorganic encapsulation layer 143. The atomic ratio of nitrogen to silicon (N/Si ratio) in the second inorganic encapsulation layer 143 may be greater than the atomic ratio of nitrogen to silicon (N/Si ratio) in the first inorganic encapsulation layer 142, and the atomic ratio of nitrogen to silicon (N/Si ratio) in the third inorganic encapsulation layer 144. The atomic ratio of nitrogen to silicon (N/Si ratio) in the third inorganic encapsulation layer 144 may be smaller than the atomic ratio of nitrogen to silicon (N/Si ratio) in the organic-inorganic hybrid layer 141, and the atomic ratio of nitrogen to silicon (N/Si ratio) in the second inorganic encapsulation layer 143.

The atomic ratio of nitrogen to silicon (N/Si ratio) in the organic-inorganic hybrid layer 141 may be the same as or similar to the atomic ratio of nitrogen to silicon (N/Si ratio) in the second inorganic encapsulation layer 143. In an embodiment of the present invention, the atomic ratio of nitrogen to silicon (N/Si ratio) in the organic-inorganic hybrid layer 141 may be greater than the atomic ratio of nitrogen to silicon (N/Si ratio) in the second inorganic encapsulation layer 143. The atomic ratio of nitrogen to silicon (N/Si ratio) in the first inorganic encapsulation layer 142 may be the same as or similar to the atomic ratio of nitrogen to silicon (N/Si ratio) in the third inorganic encapsulation layer 144. In an embodiment of the present invention, the atomic ratio of nitrogen to silicon (N/Si ratio) in the first inorganic encapsulation layer 142 may be the same as the atomic ratio of nitrogen to silicon (N/Si ratio) in the third inorganic encapsulation layer 144.

In an embodiment of the present invention, the atomic ratio of nitrogen to silicon (N/Si ratio) in the organic-inorganic hybrid layer 141 may be greater than or equal to 0.77. The atomic ratio of nitrogen to silicon (N/Si ratio) in the first inorganic encapsulation layer 142 may be less than or equal to 0.75. The atomic ratio of nitrogen to silicon (N/Si ratio) in the second inorganic encapsulation layer 143 may be greater than or equal to 0.77. The atomic ratio of nitrogen to silicon (N/Si ratio) in the third inorganic encapsulation layer 144 may be less than or equal to 0.75. The atomic ratio of nitrogen to silicon (N/Si ratio) in the organic-inorganic hybrid layer 141 and the atomic ratio of nitrogen to silicon (N/Si ratio) in the second inorganic encapsulation layer 143 may each be less than or equal to about 1. The atomic ratio of nitrogen to silicon (N/Si ratio) in the first inorganic encapsulation layer 142 and the atomic ratio of nitrogen to silicon (N/Si ratio) in the third inorganic encapsulation layer 144 may each be greater than or equal to about 0.5.

The atomic ratio of nitrogen to silicon (N/Si ratio) can be obtained through cross-sectional analysis (TEM-EDS) and compositional analysis (XPS), but the present disclosure is not necessarily limited thereto.

The organic-inorganic hybrid layer 141 and the second inorganic encapsulation layer 143 may have a lower film density than the first inorganic encapsulation layer 142 and the third inorganic encapsulation layer 144. In addition, the film density of the organic-inorganic hybrid layer 141 may be relatively low compared to other layers of the encapsulation layer 140. In other words, the film density of the organic-inorganic hybrid layer 141 may be smaller than the film density of the first inorganic encapsulation layer 142, the film density of the second inorganic encapsulation layer 143, and the film density of the third inorganic encapsulation layer 144.

The film density of the first inorganic encapsulation layer 142 may be greater than the film density of the organic-inorganic hybrid layer 141 and the film density of the second inorganic encapsulation layer 143. The film density of the first inorganic encapsulation layer 142 may be the same or similar to the film density of the third inorganic encapsulation layer 144.

The film density of the second inorganic encapsulation layer 143 may be greater than the film density of the organic-inorganic hybrid layer 141 but may be smaller than the film density of the first inorganic encapsulation layer 142 and the film density of the third inorganic encapsulation layer 144.

In an embodiment of the present invention, the film density of the organic-inorganic hybrid layer 141 may be less than or equal to about 2.1 g/cm³. The film density of the organic-inorganic hybrid layer 141 may be greater than or equal to about 1.7 g/cm³. In some embodiments, the film density of the organic-inorganic hybrid layer 141 may be greater than or equal to about 1.9 g/cm³. In some embodiments, the film density of the organic-inorganic hybrid layer 141 may be greater than or equal to about 2.0 g/cm³. When satisfying the above range, the organic-inorganic hybrid layer 141 may have an enhanced planarization properties and barrier properties.

In an embodiment of the present invention, the film density of the first inorganic encapsulation layer 142 may be greater than or equal to about 2.6 g/cm³. In some embodiments, the film density of the first inorganic encapsulation layer 142 may be greater than or equal to about 2.7 g/cm³. In an embodiment of the present invention, the film density of the first inorganic encapsulation layer 142 may be less than or equal to about 3.0 g/cm³. In some embodiments, the film density of the first inorganic encapsulation layer 142 may be less than or equal to about 2.9 g/cm³.

In an embodiment of the present invention, the film density of the second inorganic encapsulation layer 143 may be less than or equal to about 2.1 g/cm³. The film density of the second inorganic encapsulation layer 143 may be greater than or equal to about 1.7 g/cm³. In some embodiments, the film density of the second inorganic encapsulation layer 143 may be greater than or equal to about 1.9 g/cm³. In some embodiments, the film density of the second inorganic encapsulation layer 143 may be greater than or equal to about 2.0 g/cm³.

In an embodiment of the present invention, the film density of the third inorganic encapsulation layer 144 may be greater than or equal to about 2.6 g/cm³. In some embodiments, the film density of the third inorganic encapsulation layer 144 may be greater than or equal to about 2.7 g/cm³. In an embodiment of the present invention, the film density of the third inorganic encapsulation layer 144 may be less than or equal to about 3.0 g/cm³. In some embodiments, the film density of the third inorganic encapsulation layer 144 may be less than or equal to about 2.9 g/cm³.

The encapsulation layer 140 of the display device 10 may include a low-density organic-inorganic hybrid layer 141, a high-density first inorganic encapsulation layer 142, a low-density second inorganic encapsulation layer 143, and a high-density third inorganic encapsulation layer to make the overall thickness of the encapsulation layer 140 to be thin. The first inorganic encapsulation layer 142 may have a relatively high density and a small thickness t2. The thickness t2 of the first inorganic encapsulation layer 142 may be significantly smaller than a thickness t3 of the second inorganic encapsule

ation layer 143. In an embodiment of the present invention, the thickness t2 of the first inorganic encapsulation layer 142 may be about 0.5 nm to 5 nm. In the above range, the first inorganic encapsulation layer 142 having a high density may be formed within a short tact time.

The second inorganic encapsulation layer 143 may have a relatively low density and the thick thickness t3. The thickness t3 of the second inorganic encapsulation layer 143 may be significantly greater than the thickness t2 of the first inorganic encapsulation layer 142 and a thickness t4 of the third inorganic encapsulation layer 144. The thickness t3 of the second inorganic encapsulation layer 143 may be greater than the sum of the thickness t2 of the first inorganic encapsulation layer 142 and the thickness t4 of the third inorganic encapsulation layer 144. In an embodiment of the present invention, the thickness t3 of the second inorganic encapsulation layer 143 may be about 10 nm to 500 nm. In some embodiments, the thickness t3 of the second inorganic encapsulation layer 143 may be less than or equal to about 300 nm. In the above range, moisture permeation from the outside air can be prevented.

The third inorganic encapsulation layer 144 may have a relatively high density and a small thickness t4. The thickness t4 of the third inorganic encapsulation layer 144 may be significantly smaller than the thickness t3 of the second inorganic encapsulation layer 143. In an embodiment of the present invention, the thickness t4 of the third inorganic encapsulation layer 144 may be about 0.5 nm to 5 nm. In the above range, the third inorganic encapsulation layer 144 having a high density may be formed within a short tact time.

The organic-inorganic hybrid layer 141 may have a planarization function and may have different thicknesses for each area or location.

The thickness of the encapsulation layer 140 may be less than or equal to 2 μm. In an embodiment of the present invention, the sum of the thicknesses (t1+t2+t3+t4) of the organic-inorganic hybrid layer 141, the first inorganic encapsulation layer 142, the second inorganic encapsulation layer 143, and the third inorganic encapsulation layer 144 may be less than or equal to about 2 μm. Even when the thickness of the organic-inorganic hybrid layer 141 varies depending on the area or location, the thickness of the encapsulation layer 140 including the organic-inorganic hybrid layer 141 may not exceed 2 μm. In an embodiment of the present invention, the sum of the thicknesses (t1+t2+t3+t4) of the organic-inorganic hybrid layer 141, the first inorganic encapsulation layer 142, the second inorganic encapsulation layer 143, and the third inorganic encapsulation layer 144 may be greater than or equal to about 200 nm. In some embodiments, the overall thickness of the encapsulation layer 140 may become thinner. Even when the organic-inorganic hybrid layer 141, the first inorganic encapsulation layer 142, the second inorganic encapsulation layer 143, and the third inorganic encapsulation layer 144 have a thin thickness adjusted within the above-mentioned range, they may have sufficient encapsulation characteristics.

The refractive index of the organic-inorganic hybrid layer 141 may be smaller than the refractive index of the first inorganic encapsulation layer 142 and the refractive index of the third inorganic encapsulation layer 144. The refractive index of the organic-inorganic hybrid layer 141 may be the same or similar to the refractive index of the second inorganic encapsulation layer 143. In an embodiment of the present invention, the refractive index of the organic-inorganic hybrid layer 141 may be smaller than the refractive index of the second inorganic encapsulation layer 143. The refractive index of the first inorganic encapsulation layer 142 may be greater than the refractive index of the organic-inorganic hybrid layer 141 and the refractive index of the second inorganic encapsulation layer 143. The refractive index of the first inorganic encapsulation layer 142 may be the same or similar to the refractive index of the third inorganic encapsulation layer 144. The refractive index of the second inorganic encapsulation layer 143 may be smaller than the refractive index of the first inorganic encapsulation layer 142 and the refractive index of the third inorganic encapsulation layer 144.

In an embodiment, the refractive index of the organic-inorganic hybrid layer 141 may range from about 1.75 to 1.90. The refractive index of the first inorganic encapsulation layer 142 may range from about 1.85 to 2.10. The refractive index of the second inorganic encapsulation layer 143 may range from about 1.75 to 1.90. The refractive index of the third inorganic encapsulation layer 144 may range from about 1.85 to 2.10.

Herein, the film density and the thickness may be measured with an Xray reflectometer (XRR) (D8 ADVANCE Plus, Bruker). In the present specification, the refractive index may be measured using an optical measuring instrument such as an ellipsometer, a spectral reflectometer, or the like. The ellipsometer may measure the refractive index by measuring the amount of change in polarization of incident light and reflected light with respect to the inorganic layer and calculating the thickness and complex refractive index of the inorganic layer. The spectral reflectometer may measure the refractive index of the inorganic layer by comparing the intensity of light acquired by changing the wavelength. The refractive index may be a value measured at room temperature and normal pressure.

In an embodiment of the present invention, a water vapor transmission rate (WVTR) of the encapsulation layer 140 may be less than or equal to about 5*10⁻⁵ g/m² day. The encapsulation layer 140 may have a four-layer structure, yet have the small thickness described above, and have excellent barrier properties.

Herein, the water vapor transmission rate (WVTR) is a numerical value of moisture permeability that represents the amount of moisture passing through a particular film or layer in a unit area for a unit time. The water vapor transmission rate (WVTR) may be measured according to the regulations in ASTM F1249. The water vapor transmission rate (WVTR) may be measured using Mocon's AQUATRAN 2 or AQUATRAN 3 equipment.

A bottom surface of the first inorganic encapsulation layer 142 may be in contact with a top surface of the organic-inorganic hybrid layer 141 and a top surface of the first inorganic layer 142 may be in contact with a bottom surface of the second inorganic encapsulation layer 143. For example, the first inorganic encapsulation layer 142 may be disposed between the organic-inorganic hybrid layer 141 and the second inorganic encapsulation layer 143. A bottom surface of the third inorganic encapsulation layer 144 may be in contact with a top surface of the second inorganic encapsulation layer 143. The organic-inorganic hybrid layer 141 may be in contact with a second electrode ET2 (refer to FIG. 4), a capping layer, or a pixel defining layer 131 (refer to FIG. 4) on its bottom surface. The third inorganic encapsulation layer 144 may be in contact with a sensor layer or a color filter layer on its top surface.

The encapsulation layer 140 may additionally include an organic encapsulation layer other than the organic-inorganic hybrid layer 141, the first inorganic encapsulation layer 142, the second inorganic encapsulation layer 143, and the third inorganic encapsulation layer 144. The organic encapsulation layer may include an organic material, and the organic material may include a polymer such as acrylic resin, epoxy resin, polyimide, or polyethylene, but is not necessarily limited thereto.

The display device 10 may include the color filter layer 150 (refer to FIG. 4) disposed on the encapsulation layer 140. The color filter layer 150 may include a plurality of color filters 151, 152, and 153. Each of the plurality of color filters 151, 152, and 153 may include a filtering pattern area and a light blocking area. The filtering pattern area may overlap the emission area EA, and may form a light exit area in which light emitted from the emission area EA exits. The light blocking area is an area through in which light cannot pass due to the stacking of the plurality of color filters 151, 152, and 153.

The color filters 151, 152, and 153 may include a first color filter 151, a second color filter 152, and a third color filter 153 that respectively correspond to different emission areas EA. The color filters 151, 152, and 153 may include a colorant, such as a dye or a pigment, that absorbs light in a wavelength band other than a specific wavelength band, and may be arranged corresponding to the color of the light emitted from the emission area EA. For example, the first color filter 151 may be a red color filter that transmits only a first light that is red. The second color filter 152 may be a green color filter that transmits only a second light that is green, and the third color filter 153 may be a blue color filter that transmits only a third light that is blue. FIG. 4 illustrates that only the filtering pattern area of the second color filter 152 overlaps the emission area EA, but the emission areas of other adjacent sub-pixels may overlap the filtering pattern area of the first color filter 151 or the filtering pattern area of the third color filter 153.

The display device 10 may reduce the intensity of reflected light caused by external light as the color filters 151, 152, and 153 are arranged in an overlapping manner. The color of the reflected light caused by the external light may be controlled by adjusting the arrangement, shape, area, and the like of the color filters 151, 152, and 153 in plan view.

An overcoat layer OC (refer to FIG. 4) may be disposed on the color filter layer 150 and planarize the top ends of the color filters 151, 152, and 153. The overcoat layer OC may be a colorless light transmissive layer that does not have a color in a visible light band. For example, the overcoat layer OC may include a colorless light transmissive organic material such as an acrylic resin.

Hereinafter, a fabrication method of the display device 10 will be described with reference to other drawings.

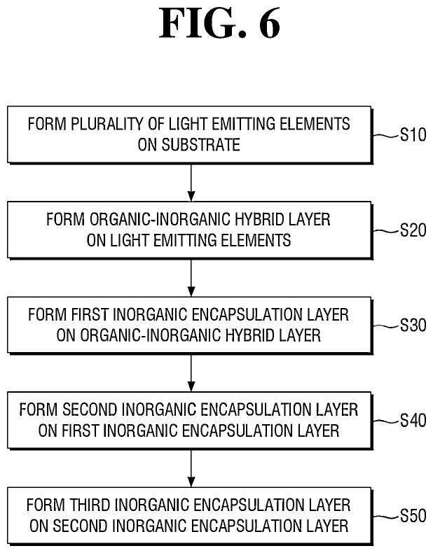

FIG. 6 is a flowchart illustrating a method of fabrication for the display device according to an embodiment of the present invention.

Referring to FIG. 6, the fabrication method of the display device 10 according to an embodiment of the present invention may include forming the plurality of light emitting elements EL on the substrate (step S10), forming the organic-inorganic hybrid layer 141 on the light emitting elements EL (step S20), forming the first inorganic encapsulation layer 142 on the organic-inorganic hybrid layer 141 (step S30), forming the second inorganic encapsulation layer 143 on the first inorganic encapsulation layer 142 (step S40), and forming the third inorganic encapsulation layer 144 on the second inorganic encapsulation layer 143 (step S50).

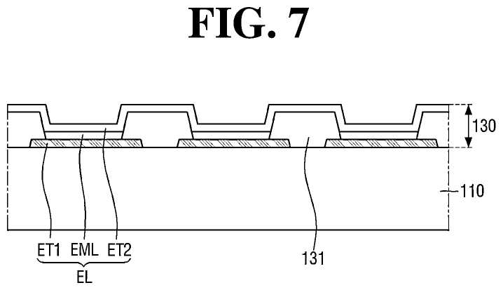

FIGS. 7 to 11 are diagrams sequentially showing a fabrication process of a display device according to an embodiment of the present invention.

Referring to FIG. 7, the plurality of light emitting elements EL are formed on the substrate 110 (step S10) to form the light emitting element layer 130. The pixel defining layer 131 may be formed on the substrate 110, and the plurality of light emitting elements EL may be formed in openings of the pixel defining layer 131. The structure of the pixel defining layer 131 and the light emitting elements EL are the same as described above. Each of these formation processes may be performed by a typical patterning process, a deposition process, or the like.

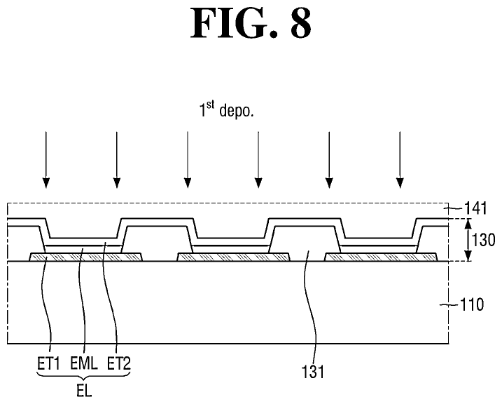

Referring to FIG. 8, the organic-inorganic hybrid layer 141 may be formed on the light emitting elements EL at a first deposition rate v1 (step S20). Step S20 of forming the organic-inorganic hybrid layer 141 may be performed using a plasma chemical vapor deposition (PECVD) process, but is not necessarily limited thereto.

Step S20 of forming the organic-inorganic hybrid layer 141 may be performed using an organic silicon precursor and/or an aminosilane precursor. Carbon (C) and nitrogen (N) may be derived from organic silicon precursor and aminosilanes. In an embodiment of the present invention, the organic silicon precursor may include at least one of hexamethyldisiloxane (HMDSO), dimethylamino dimethylsilane (DMADMS), bis(dimethylamino)methylsilane (BDMAMS), hexamethyldisilazane, hexamethylcyclotrisilazane, hexamethyldisilazane (HMDS), tetraethoxysilane, tetramethylsilane, or tetraethylsilane. In an embodiment of the present invention, the aminosilane precursor may include at least one of cyclosilazane, trisilylamine, bis(diethylamino) silane (BDEAS), bis(t-butylamino) silane (BTBAS), tris(dimethylamino) silane, tris(isopropylamino) silane, tetrakis(dimethylamino) silane, tri (isopropyl)cyclotrisilazane, or tetramethyldisilazane, but is not necessarily limited thereto.

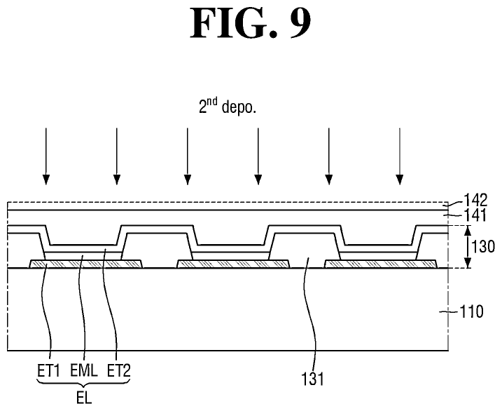

Referring to FIG. 9, the first inorganic encapsulation layer 142 may be formed on the organic-inorganic hybrid layer 141 at a second deposition rate v2 (step S30). Step S30 of forming the first inorganic encapsulation layer 142 may be performed using a plasma atomic layer deposition (PEALD) or plasma chemical vapor deposition (PECVD) process.

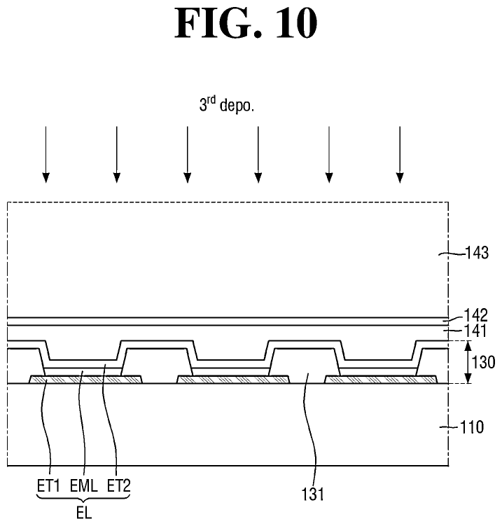

Referring to FIG. 10, the second inorganic encapsulation layer 143 may be formed on the first inorganic encapsulation layer 142 at a third deposition rate v3 (step S40). Step S40 of forming the second inorganic encapsulation layer 143 may be performed using a plasma chemical vapor deposition (PECVD) process, but is not necessarily limited thereto.

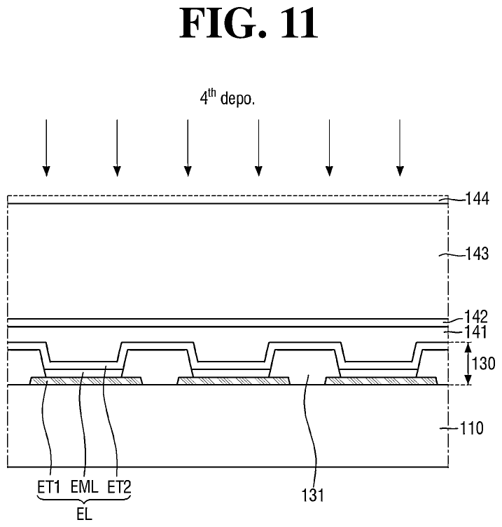

Referring to FIG. 11, the third inorganic encapsulation layer 144 may be formed on the second inorganic encapsulation layer 143 at a fourth deposition rate v4 (step S50). Step S50 of forming the third inorganic encapsulation layer 144 may be performed using a plasma atomic layer deposition (PEALD) or plasma chemical vapor deposition (PECVD) process.

Step S30 of forming the first inorganic encapsulation layer 142 to step S50 of forming the third inorganic encapsulation layer 144 may be performed using the aminosilane precursor which has an Si—N bond as a core structure. The aminosilane precursor may include a specific compound of the aminosilane precursor described above in the step S20 of forming the organic-inorganic hybrid layer 141.

In an embodiment of the present invention, the first deposition rate v1 may be greater than the second deposition rate v2 and the fourth deposition rate v4. The third deposition rate v3 may be greater than the second deposition rate v2 and the fourth deposition rate v4. The first deposition rate v1 and the third deposition rate v3 may be the same or different and be greater than or equal to about 30 nm/min. The second deposition rate v2 and the fourth deposition rate v4 may be the same or different and be less than or equal to about 30 nm/min. Accordingly, the film density of each of the first inorganic encapsulation layer 142 and the third inorganic encapsulation layer 144 may be greater than that of each of the organic-inorganic hybrid layer 141 and the second inorganic encapsulation layer 143.

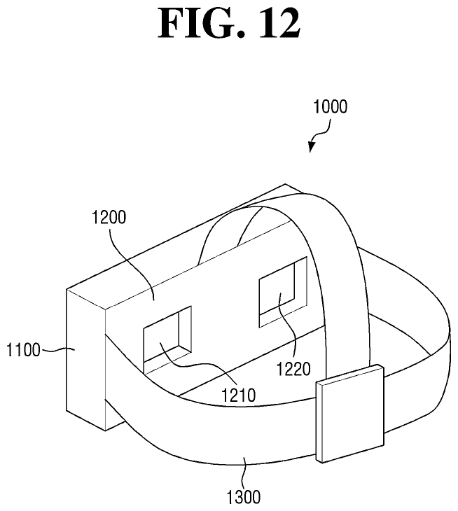

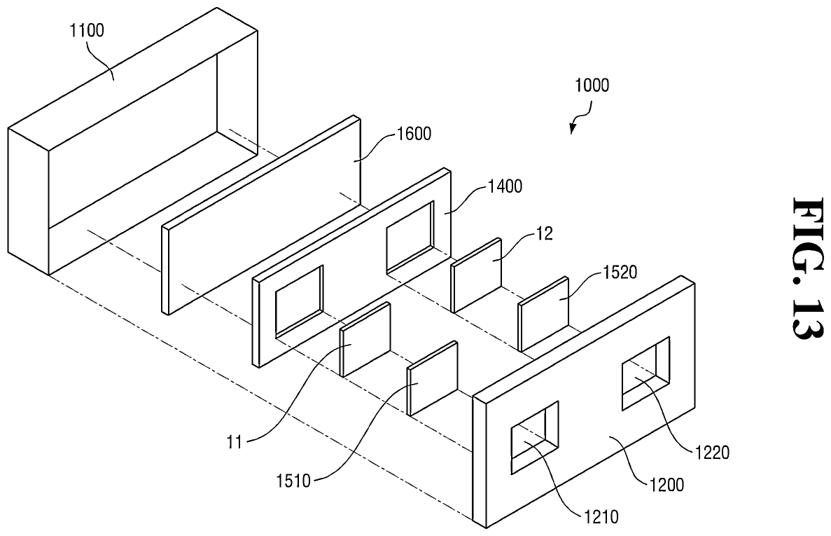

FIG. 12 is a perspective view illustrating a head mounted display according to an embodiment of the present invention. FIG. 13 is an exploded perspective view showing an example of the head mounted display of FIG. 12.

Referring to FIGS. 12 and 13, a head mounted display 1000 according to an embodiment of the present invention includes a first display device 11, a second display device 12, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector.

The first display device 11 may provide an image to a user's left eye, and the second display device 12 may provide an image to a user's right eye. To the extent that elements such as the first display device 11 and the second display device 12 have not been described in detail, it may be assumed that the element is at least similar to corresponding elements that have been described in FIG. 1.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600 and between the second display device 12 and the control circuit board 1600. The middle frame 1400 may support and fix the first display device 11, the second display device 12, and the control circuit board 1600.

The control circuit board 1600 may be disposed between the middle frame 1400 and the display device housing 1100. The control circuit board 1600 may be connected to the first display device 11 and the second display device 12 through the connector. The control circuit board 1600 may convert an image source inputted from the outside into the digital video data, and may transmit the digital video data to the first display device 11 and the second display device 12 through the connector.

The control circuit board 1600 may transmit the digital video data corresponding to a left-eye image optimized for the user's left eye to the first display device 11 and may transmit the digital video data corresponding to a right-eye image optimized for the user's right eye to the second display device 12. Alternatively, the control circuit board 1600 may transmit the same digital video data to the first display device 11 and the second display device 12.

The display device housing 1100 serves to accommodate the first display device 11, the second display device 12, the middle frame 1400, the first optical member 1510, the second optical member 1520, the control circuit board 1600, and the connector. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 15 and 16 illustrate that the first eyepiece 1210 and the second eyepiece 1220 are disposed separately, but the present disclosure is not necessarily limited thereto. For example, the first eyepiece 1210 and the second eyepiece 1220 may be combined into one.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1100 is implemented to be lightweight and compact, the head mounted display 1000 may be provided with, as shown in FIG. 15, an eyeglass frame instead of the head mounted band 1300.

In addition, the head mounted display 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

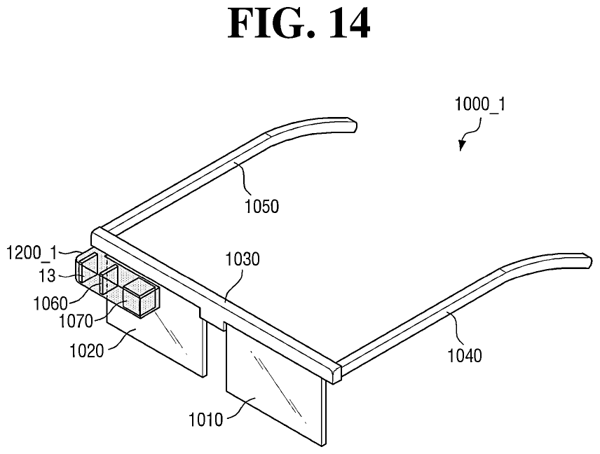

FIG. 14 is a perspective view illustrating a head mounted display according to an embodiment of the present invention.

Referring to FIG. 14, a head mounted display 1000_1 according to an embodiment of the present invention may be an eyeglasses-type display device in which a display device housing 1200_1 is implemented in a lightweight and compact manner. The head mounted display 1000_1 according to an embodiment of the present invention may include a display device 13, a left eye lens 1010, a right eye lens 1020, a support frame 1030, temples 1040 and 1050, an optical member 1060, an optical path changing member 1070, and the display device housing 1200_1.

The display device housing 1200_1 may include the display device 13, the optical member 1060, and the optical path changing member 1070. An image displayed on the display device 13 may be magnified by the optical member 1060, and the optical path may be changed by the optical path changing member 1070 to provide the image to the user's right eye through the right eye lens 1020. As a result, the user may view an augmented reality image through the right eye, in which a virtual image displayed on the display device 13 and a real image seen through the right eye lens 1020 are combined.

FIG. 14 illustrates that the display device housing 1200_1 is disposed at the right end of the support frame 1030, but the present disclosure is not necessarily limited thereto. For example, the display device housing 1200_1 may be disposed on the left end of the support frame 1030, and in this case, the image of the display device 13 may be provided to the user's left eye. In some embodiments, the display device housing 1200_1 may be disposed on both the left and right ends of the support frame 1030, and in this case, the user may view the image displayed on the display device 13 through both the left and right eyes.

In concluding the detailed description, those skilled in the art will appreciate that many variations and modifications can be made to the preferred embodiments without substantially departing from the principles of the present disclosure. Therefore, the disclosed preferred embodiments of the invention are not for purposes of limitation.

What is claimed is:

1. A display device comprising:
a light emitting element layer disposed on a substrate and comprising a plurality of light emitting elements; and
an encapsulation layer comprising an organic-inorganic hybrid layer disposed on the light emitting element layer, a first inorganic encapsulation layer disposed on the organic-inorganic hybrid layer, a second inorganic encapsulation layer disposed on the first inorganic encapsulation layer, and a third inorganic encapsulation layer disposed on the second inorganic encapsulation layer,
wherein the organic-inorganic hybrid layer contains silicon, carbon and nitrogen,
wherein the first inorganic encapsulation layer, the second inorganic encapsulation layer and the third inorganic encapsulation layer each contains silicon and nitrogen, and
wherein an atomic ratio of nitrogen to silicon (N/Si ratio) in the organic-inorganic hybrid layer is greater than an atomic ratio of nitrogen to silicon (N/Si ratio) in the first inorganic encapsulation layer and an atomic ratio of nitrogen to silicon (N/Si ratio) in the third inorganic encapsulation layer.

2. The display device of claim 1,
wherein a film density of the organic-inorganic hybrid layer is smaller than a film density of the first inorganic encapsulation layer, a film density of the second inorganic encapsulation layer, and a film density of the third inorganic encapsulation layer.

3. The display device of claim 2,
wherein the film density of the first inorganic encapsulation layer is greater than the film density of the second inorganic encapsulation layer.

4. The display device of claim 3,
wherein the film density of the first inorganic encapsulation layer is the same as the film density of the third inorganic encapsulation layer.

5. The display device of claim 1,
wherein the film density of the organic-inorganic hybrid layer is less than or equal to about 2.1 g/cm³,
the film density of the first inorganic encapsulation layer is greater than or equal to about 2.6 g/cm³,
the film density of the second inorganic encapsulation layer is less than or equal to about 2.1 g/cm³, and
the film density of the third inorganic encapsulation layer is greater than or equal to about 2.6 g/cm³.

6. The display device of claim 1,
wherein the atomic ratio of nitrogen to silicon (N/Si ratio) in the organic-inorganic hybrid layer is greater than or equal to about 0.77,
wherein the atomic ratio of nitrogen to silicon (N/Si ratio) in the first inorganic encapsulation layer is less than or equal to about 0.75,
wherein the atomic ratio of nitrogen to silicon (N/Si ratio) in the second inorganic encapsulation layer is greater than or equal to about 0.77, and
wherein the atomic ratio of nitrogen to silicon (N/Si ratio) in the third inorganic encapsulation layer is less than or equal to about 0.75.

7. The display device of claim 1,
wherein the organic-inorganic hybrid layer contains silicon oxycarbonitride (SiOₓC_{y}N_{z}) or silicon carbonitride (SiC_{y}N_{z}), and
wherein the first inorganic encapsulation layer, the second inorganic encapsulation layer and the third inorganic encapsulation layer each contains silicon nitride (SiN_{z}).

8. The display device of claim 1,
wherein the organic-inorganic hybrid layer comprises organic moieties, and
wherein the organic moieties are randomly disposed in the organic-inorganic hybrid layer.

9. The display device of claim 8,
wherein the organic moiety comprises at least one of an alkyl group, an alkoxy group, or an amine group.

10. The display device of claim 1,
wherein the sum of a thicknesses of the organic-inorganic hybrid layer, the first inorganic encapsulation layer, the second inorganic encapsulation layer, and the third inorganic encapsulation layer is less than or equal to about 2 μm.

11. The display device of claim 10,
wherein the thickness of the second inorganic encapsulation layer is greater than the thickness of the first inorganic encapsulation layer and the thickness of the third inorganic encapsulation layer.

12. The display device of claim 10,
wherein the thickness of the first inorganic encapsulation layer ranges from about 0.5 nm to 5 nm,
wherein the thickness of the second inorganic encapsulation layer ranges from about 10 nm to 500 nm, and
wherein the thickness of the third inorganic encapsulation layer ranges from about 0.5 nm to 5 nm.

13. The display device of claim 1,
wherein a water vapor transmission rate (WVTR) of the encapsulation layer is less than or equal to about 5*10⁻⁵ g/m² day.

14. The display device of claim 1,
wherein a refractive index of the organic-inorganic hybrid layer is smaller than a refractive index of the first inorganic encapsulation layer and a refractive index of the third inorganic encapsulation layer.

15. The display device of claim 14,
wherein the refractive index of the organic-inorganic hybrid layer ranges from about 1.75 to 1.90,
wherein the refractive index of the first inorganic encapsulation layer ranges from about 1.85 to 2.10,
wherein the refractive index of the second inorganic encapsulation layer ranges from about 1.75 to 1.90, and
wherein the refractive index of the third inorganic encapsulation layer ranges from about 1.85 to 2.10.

16. The display device of claim 1,
wherein a bottom surface of the first inorganic encapsulation layer is in contact with the organic-inorganic hybrid layer,
a top surface of the first inorganic encapsulation layer is in contact with the second inorganic encapsulation layer, and
a bottom surface of the third inorganic encapsulation layer is in contact with the second inorganic encapsulation layer.

17. A method of fabrication for a display device, comprising:
forming a light emitting element layer comprising a plurality of light emitting elements on a substrate;
forming an organic-inorganic hybrid layer on the light emitting element layer at a first deposition rate;
forming a first inorganic encapsulation layer on the organic-inorganic hybrid layer at a second deposition rate;
forming a second inorganic encapsulation layer on the first inorganic encapsulation layer at a third deposition rate; and
forming a third inorganic encapsulation layer on the second inorganic encapsulation layer at a fourth deposition rate,
wherein the first deposition rate is greater than the second deposition rate and the fourth deposition rate, and the third deposition rate is greater than the second deposition rate and the fourth deposition rate.

18. The method of claim 17,
wherein each of the first and third deposition rates is greater than or equal to about 30 nm/min, and each of the second and fourth deposition rates is less than or equal to about 30 nm/min.

19. The method of claim 17,
wherein the forming the organic-inorganic hybrid layer on the light emitting element layer at the first deposition rate uses an organic silicon precursor or an aminosilane precursor,
wherein the organic silicon precursor comprises at least one of hexamethyldisiloxane (HMDSO), dimethylamino dimethylsilane (DMADMS), bis(dimethylamino)methylsilane (BDMAMS), hexamethyldisilazane, hexamethylcyclotrisilazane, hexamethyldisilazane (HMDS), tetraethoxysilane, tetramethylsilane, or tetraethylsilane, and
wherein the aminosilane precursor comprises at least one of cyclosilazane, trisilylamine, bis(diethylamino)silane (BDEAS), bis(t-butylamino)silane (BTBAS), tris(dimethylamino)silane, tris(isopropylamino)silane, tetrakis(dimethylamino)silane, tri(isopropyl)cyclotrisilazane, or tetramethyldisilazane.

20. The method of claim 15,
wherein the forming the organic-inorganic hybrid layer and the forming the second inorganic encapsulation layer are performed using a plasma chemical vapor deposition (PECVD) process, and
the forming the first inorganic encapsulation layer and the forming the third inorganic encapsulation layer are performed using a plasma atomic layer deposition (PEALD) or plasma chemical vapor deposition (PECVD) process.
